(19) United States
(12) Patent Application Publication
(10) Pub. No.: US 2003/0015421 A1
(43) Pub. Date: Jan. 23, 2003

(54) Collimated sputtering of cobalt

(75) Inventors: Yonghwa Chris Cha, San Jose, CA (US); Ki Hwan Yoon, Sunnyvale, CA (US); Jin-Hyun Kim, San Jose, CA (US); Sang Ho Yu, Sunnyvale, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/910,585

(22) Filed: Jul. 20, 2001

(51) Int. Cl. C23C 14/34

(52) U.S. Cl. 204/298.19; 204/298.11; 204/298.15; 204/298.07; 204/298.06; 204/298.08

(57) ABSTRACT

A magnetron sputter reactor particularly useful for sputtering a magnetic material such as cobalt into high aspect-ratio holes of a wafer. A magnetron is positioned in back of the target which is spaced from the pedestal supporting the wafer by at least 50% of the wafer diameter in a long-throw configuration. A grounded collimator is additionally placed between the target and wafer, preferably relatively close to the target to mostly confine plasma near the target. A grounded shield protects the sides and bottom of the chamber and the pedestal sides from sputter deposition, and it supports the collimator on a ledge in its middle.

### BACKGROUND OF THE INVENTION

1. Field of the Invention

The invention relates generally to the method and apparatus of sputtering of materials. In particular, the invention relates to the sputtering of magnetic materials.

2. Background Art

Sputtering, alternatively called physical vapor deposition (PVD), is the most prevalent method of depositing layers of metals and related materials in the fabrication of semiconductor integrated circuits. Although sputtering is most widely practiced in depositing metallization layers of aluminum or copper, it is also used to deposit refractory metals for a number of purposes. One application is part of the process for forming a salicide, a term derived from self-aligned silicide. For example, as illustrated in the cross-sectional view of FIG. 1, a pair of MOS transistors are formed over a silicon substrate 10 in an area between two thermal oxide isolation regions 12. Two gate structures 14, 16 are first defined, each including a thin gate oxide layer 18 and a polysilicon gate layer 20. By well known techniques including conformal deposition and directional and selective etching, oxide spacers 22 are formed on the sides of the gate structures 12, 16. The gate structures 14, 16 and the isolation regions 12 act as a mask for ion implantation of a dopant which forms, in combination with a drive-in anneal, a doped source region 24 and doped drain regions 26 that are self-aligned to the gate structures 14, 16.

A nearly conformal layer 28 of a refractory metal, such as titanium, is deposited over both the oxide isolation regions 12 and spacer 22 and over the exposed portions of the silicon substrate 10 and the polysilicon gate layer 20. A gap 29 between the two gate structures 14, 16 tends to present the greatest challenge in the conformal metal deposition, particularly when performed by sputtering, because of its relatively high aspect ratio resulting from the desire to make the structures as dense as possible. On the other hand, the portions of the metal layer 28 above the gate structures 14, 16 are completely exposed and easily deposited by sputtering. After the refractory metal layer 28 has been deposited, one or more high temperature anneals are performed to react the refractory metal with the silicon to form a disilicide such as TiSi_{2.} The refractory metal does not usually react with the oxide. The unreacted refractory metal is removed to leave, as illustrated in FIG. 2, a silicided source region 30 and silicided drain regions 32 at the exposed surfaces of the silicon substrate 10 and silicided polysilicon regions 34 at the top of the polysilicon layers 20. A planarized oxide layer 36 is then deposited is photolithographically etched to form source/drain contact holes 37, 38 to the underlying silicided regions 30, 32 formed in the silicon substrate 10 and gate contact holes 39 to the underlying silicided regions 34 formed in the polysilicon layer 18. A metal, such as aluminum, copper, or tungsten is filled into the holes 37, 38, 39 to form vertical electrical interconnects, called contacts, to the underlying silicon regions. The silicide forms a good ohmic contact between the metal and the semiconducting silicon or polysilicon and also acts as a bonding layer between the metal and the silicon.

The described structures fails to show several additional layers that are typically used, such as a temporary silicon nitride protective layer over exposed silicon to protect it during etching, a temporary TiN capping layer on the refractory metal to prevent it from being oxidized in the silicidation anneal, and barrier layers formed between the oxide and the metal. However, these layers are not directly pertinent to the refractory metal layer with which the invention is described.

In the recent past, titanium silicide has been the most prevalently used silicide. However, as minimum features sizes are decreasing to 0.21 μm and below, corresponding to the width of the gap 29, cobalt suicide has become the preferred silicide for a number of reasons. As the gate line widths decrease to these small sizes, the TiSi₂ sheet resistance increases while the CoSi₂ sheet resistance does not. CoSi₂ provides better etch selectivity than TiSi₂, an important effect as the silicide thickness decreases. Also, TiSi₂ suffers from a decreases in the thermal process window of the silicidation, and from dopant effects in the silicidation rate. However, cobalt sputtering processes and equipment have not been well developed for the challenge of step coverage and bottom coverage in structures with relatively high aspect ratios.

One recently developed technique for sputtering metal into high aspect-ratio holes is self-ionized plasma (SIP) sputtering, which has been particularly developed for sputtering copper but has been found useful for aluminum as well. In this technique, a small but strong nested magnetron has a strong outer pole of one magnetic polarity surrounding a weaker inner pole of the other polarity. The magnetron is rotated about the center of a target to which a high DC power level is applied. The combination of a small strong magnetron and high power creates a relatively high plasma density in the area of the target adjacent to the rotating magnetron. As a result, a significant fraction of the metal atoms sputtered from the target is ionized to two effects. First, the metal ions can partially operate as the sputtering working gas, which is typically argon. Thereby, the argon pressure can be reduced without extinguishing the plasma. The reduced pressure reduces the temperature of the process because of the reduction of the number of argon ions and also reduces scattering of the sputtered atoms. Furthermore, the reduced argon pressure reduces scattering between the argon and the metal neutral atoms or ions, thereby increasing the mean free path of the sputtered metal atoms and thereby not creating an isotropic flux pattern near the wafer which poorly penetrates a high-aspect ratio hole. Secondly, the wafer can be electrically biased to attract and accelerate the metal ions, thereby producing a highly anisotropic sputter pattern that penetrates deep within the hole being sputter coated. The differing strengths of the poles of the magnetron, producing an unbalanced magnetron, causes the magnetic field produced by the outer pole to extend a significant distance towards the wafer. This field guides the metal ions towards the wafer.

There are at least two problems with applying the SIP process to sputtering cobalt into contact holes overlying semiconducting silicon. First and more fundamentally, cobalt is a slightly magnetic material. As a result, a cobalt target tends to magnetically short the magnetic field produced by the magnetron positioned in back of the target and hence significantly reduces the effective magnetic field in the processing space in front of the target. As a result, the plasma density is reduced so that the ionization fraction of the cobalt atoms is also reduced, and magnetic guiding is degraded. A second problem with sputtering a contact hole is that the semiconductor silicon to be coated is damaged by high energy ions, whether they be cobalt or argon, or by electrons. The electrons have the further property of charging the exposed dielectric, and the negative bias accelerates the positive ions to high energies. Damage becomes an even greater issue for devices of small dimensions. Accordingly, wafer biasing to achieve bottom coverage should be minimized.

High-density plasma (HDP) sputtering is another technique for deep hole filling. Typically, the high-density plasma is achieved by coupling RF power into the chamber through inductive coils wrapped around the chamber sidewalls or arranged in back of the target. While HDP sputtering is effective at generating high ionization fractions of sputtered atoms, it typically requires a relatively high argon chamber pressure and produces a high wafer temperature, neither of which is desired for salicidation. Furthermore, any wafer biasing also attracts and accelerates the high density of argon ions, which will strike and damage the semiconducting silicon.

In another approach for filling deep holes, a collimator is positioned between the target and the wafer relatively near the wafer to filter out the sputter flux that is far from the perpendicular to the plane of the wafer, thereby making the sputter flux incident on the wafer to be strongly peaked in the forward direction. Such a pattern easily coats the bottom of high-aspect ratio holes. Collimators are disfavored for the typical application requiring a thick sputter deposition since the holes of the collimators become clogged with the off-angle sputter particles that strike collimator hole sidewalls and deposit there. Also, collimators reduce the effective sputtering rate since only the forward component of the flux reaches the wafer.

In yet another approach called long throw, the target is positioned relatively far from the wafer so that only the nearly perpendicular sputter flux reaches the wafer, the off-angle components instead coating the shields on the chamber sidewalls. Long throw suffers the disadvantages of the need to frequently replace the shields before the extraneous coating flakes off and from the reduced effective sputtering rate resulting from using only part of the sputter flux. Furthermore, to support a plasma in a long-throw configuration requires generally higher argon pressure.

Accordingly, it is desired to sputter cobalt and other magnetic materials into the bottom of high aspect ratio holes without having to rely on strong and projecting magnetic fields, on significant wafer biasing, or on high-density plasmas. Advantageously, the chamber pressure is relatively low while still supporting the plasma. It is also desired to make the sputtering equipment be simple and economical.

### SUMMARY OF THE INVENTION

The invention includes a method of sputtering cobalt and other magnetic materials and the apparatus used to achieve it. One embodiment of the apparatus includes a grounded collimator positioned relatively close to the magnetic target, for example, separated from the target by no more than 60% and more preferably 40% of the spacing between the wafer and the target. The close spacing tends to confine a relatively high-density plasma close to the target. The plasma is supported at reduced chamber pressure. Advantageously, the target is separated from the wafer by at least 50% of the wafer diameter in a long-throw configuration.

In one aspect of the invention, a grounded shield protecting the side and bottom walls of the chamber and the sides of the pedestal from sputter deposition also supports the collimator.

Advantageously, the chamber pressure, for example of argon working gas, is maintained at no more than 2 milliTorr, preferably at less than 1 milliTorr.

### BRIEF DESCRIPTION OF THE DRAWINGS

FIG. 1 is a cross-sectional view of a partially formed pair of MOS transistors.

FIG. 2 is a cross-sectional view of the pair of MOS transistors including contact holes in the overlying dielectric layer.

FIG. 3 is a cross-sectional view of a sputtering chamber included within the invention.

FIG. 4 is an expanded view of FIG. 3 including upper area of the shields near the target.

FIG. 5 is a plan view of a ring collimator.

FIG. 6 is a partial plan view of honeycomb collimator.

### DETAILED DESCRIPTION OF THE PREFERRED EMBODIMENTS

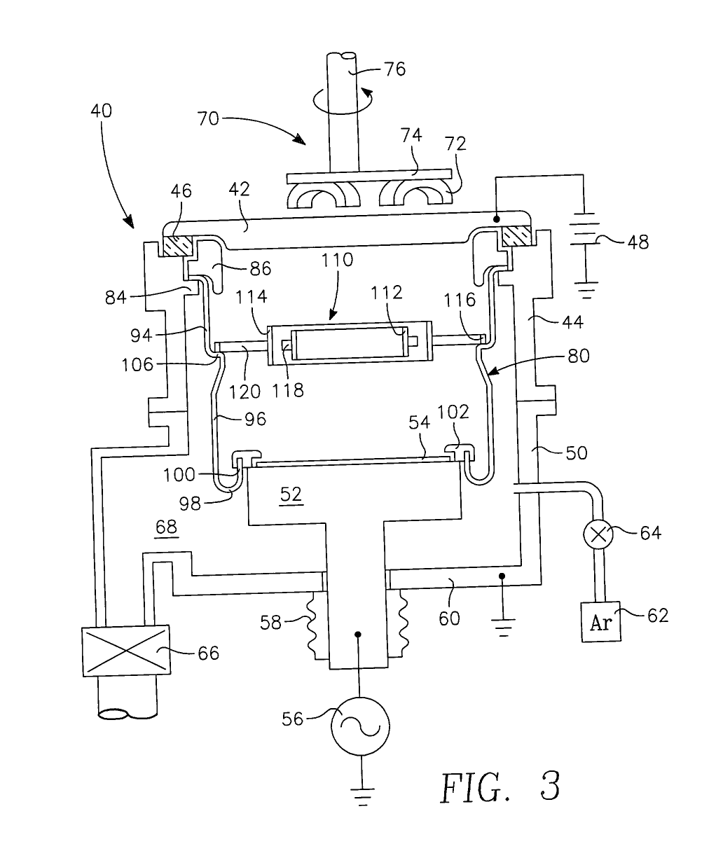

A first embodiment of a sputtering reactor 40 of the invention is illustrated in the cross-sectional view of FIG. 3. The reactor includes a cobalt target 42 supported on and sealed by O-rings to a grounded conductive aluminum adapter 44 through a dielectric isolator 46. The target 42 may be a bonded composite of a metallic cobalt surface layer and a backing plate of a more workable metal. A controllable DC power source 48 applies a negative voltage to the target 42, typically in the neighborhood of −400 to −600VDC in order to support a plasma in the 0chamber. The adapter 44 in turn is sealed and grounded to an aluminum chamber sidewall 50. The adapter 44 allows the throw length to be changed by changing a relatively simple part. A pedestal 52 supports a wafer 54 to be sputter coated in planar opposition to the principal face of the target 42. In the specific embodiment, the separation between the target 42 and the wafer 54 is 150-300 mm for a 200 mm wafer 54 or 200-400 mm for a 300 mm wafer 54. Any ratio between separation and wafer diameter of greater than 50% is considered long throw. An RF power supply 56 in some applications is connected to the pedestal electrode 52 in order to induce a negative DC self-bias on the wafer 54, but in other applications the pedestal 52 is grounded or left electrically floating. The pedestal 52 is vertically movable through a bellows 58 connected to a lower chamber wall 60 to allow the wafer 54 to be transferred onto the pedestal 52 through an unillustrated load lock valve in the lower portion of the chamber and thereafter raised to a deposition position.

Argon working gas is supplied from a gas source 62 through a mass flow controller 64 into the lower part of the chamber. A vacuum pumping system 66 connected through a pumping port 68 in the lower chamber is capable of maintaining the chamber at a base pressure of less than 10⁻⁶ Torr, but the argon pressure within the chamber is typically maintained at between 0.2 and 2 milliTorr, preferably less than 1 milliTorr, for cobalt sputtering.

A rotatable magnetron 70 is positioned in back of the target 42 and includes a plurality of horseshoe magnets 72 supported by a base plate 74 connected to a rotation shaft 76 coincident with the central axis of the chamber 40 and the wafer 54. The horseshoe magnets 72 are arranged in closed pattern typically having a kidney shape. They produce a magnetic field within the chamber, generally parallel and close to the front face of the target 42 to trap electrons and thereby increase the local plasma density, which in turn increases the sputtering rate. The magnets 72 are rotated so as to more uniformly sputter the target 42 and coat the wafer 54.

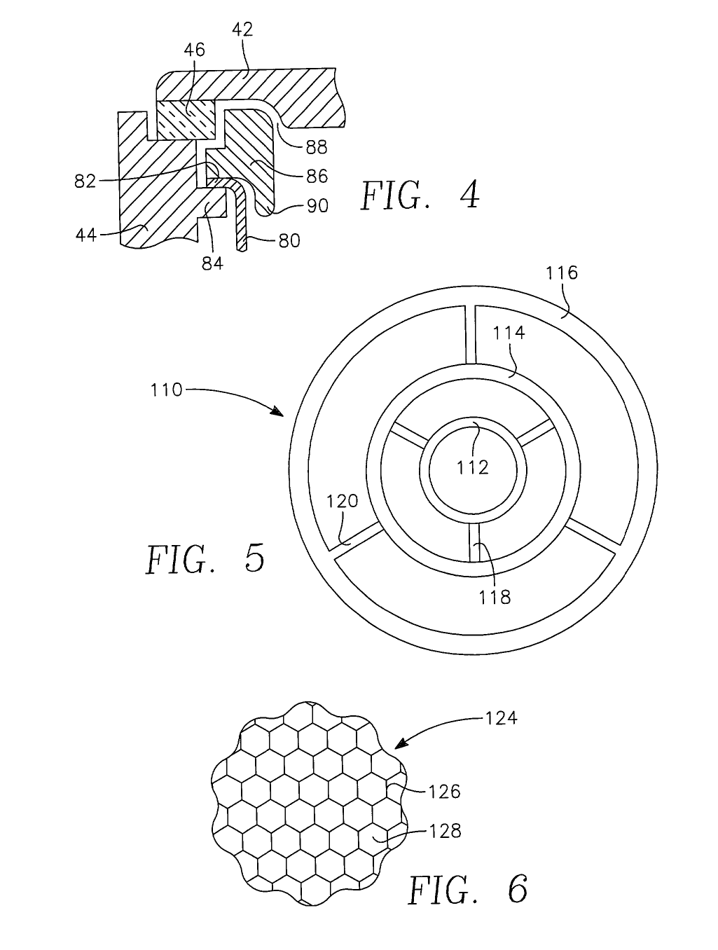

The reactor 40 of the invention includes a grounded bottom shield 80 having, as is more clearly illustrated in the exploded cross-sectional view of FIG. 4, an upper flange 82 supported on and electrically connected to a ledge 84 of the adapter 44. A dark space shield 86 is supported on the flange 82 of the bottom shield 80, and unillustrated screws recessed in the upper surface of the dark space shield 86 fix it and the flange 82 to the adapter ledge 84 having tapped holes receiving the screws. This metallic threaded connection grounds the two shields 80, 86 to the adapter 44. Both shields 80, 86 are typically formed from hard, non-magnetic stainless steel. The dark space shield 86 has an upper portion that closely fits an annular side recess of the target 42 with a narrow gap 88 between the dark space shield 86 and the target 42 which is sufficiently narrow to prevent the plasma to penetrate, hence protecting the ceramic isolator 46 from being sputter coated with a metal layer, which would electrically short the target 42. The dark space shield 86 also includes a downwardly projecting tip 90, which prevents the interface between the bottom shield 80 and dark space shield 86 from becoming bonded by sputter deposited metal.

Returning to the overall view of FIG. 3, the bottom shield 80 extends downwardly in a upper generally tubular portion 94 of a first diameter and a lower generally tubular portion 96 of a smaller second diameter to extend generally along the walls of the adapter 44 and the chamber body 50 to below the top surface of the pedestal 52. It also has a bowl-shaped bottom including a radially extending bottom portion 98 and an upwardly extending inner portion 100 just outside of the pedestal 52. A cover ring 102 rests on the top of the upwardly extending inner portion 100 of the bottom shield 80 when the pedestal 52 is in its lower, loading position but rests on the outer periphery of the pedestal 52 when it is in its upper, deposition position to protect the pedestal 52 from sputter deposition. An additional unillustrated deposition ring may be used to shield the periphery of the wafer 54 from deposition.

The upper and lower tubular portions 94, 96 of the lower shield 80 are joined by a radially extending ledge portion 106. A metallic ring collimator 110 rests on the ledge portion 106 of the lower shield, thereby grounding the collimator 110. The ring collimator 110 includes, as better illustrated in the plan view of FIG. 5, three concentric tubular sections 112, 114, 116 linked by cross struts 118, 120. The outer tubular section 116 rests on the ledge portion 106 of the lower shield 80. The use of the lower shield 80 to support the collimator 110 simplifies the design and maintenance of the chamber. At least the two inner tubular sections 112, 114 are sufficiently high to define high aspect-ratio apertures which partially collimate the sputtered particles. Further, the upper surface of the collimator 110 acts as a ground plane in opposition to the biased target 42, particularly keeping plasma electrons away from the wafer 54.

Another type of collimator usable with the invention is a honeycomb collimator 124, partially illustrated in the plan view of FIG. 6 having a mesh structure with hexagonal walls 126 separating hexagonal apertures 128 in a close-packed arrangement. An advantage of the honeycomb collimator 124 is, if desired, the thickness of the collimator 124 can be varied from the center to the periphery of the collimator, usually in a convex shape, so that the apertures 128 have aspect ratios that are likewise varying across the collimator 124. This allows the sputter flux density to be tailored across the wafer, permitting increased uniformity of deposition.

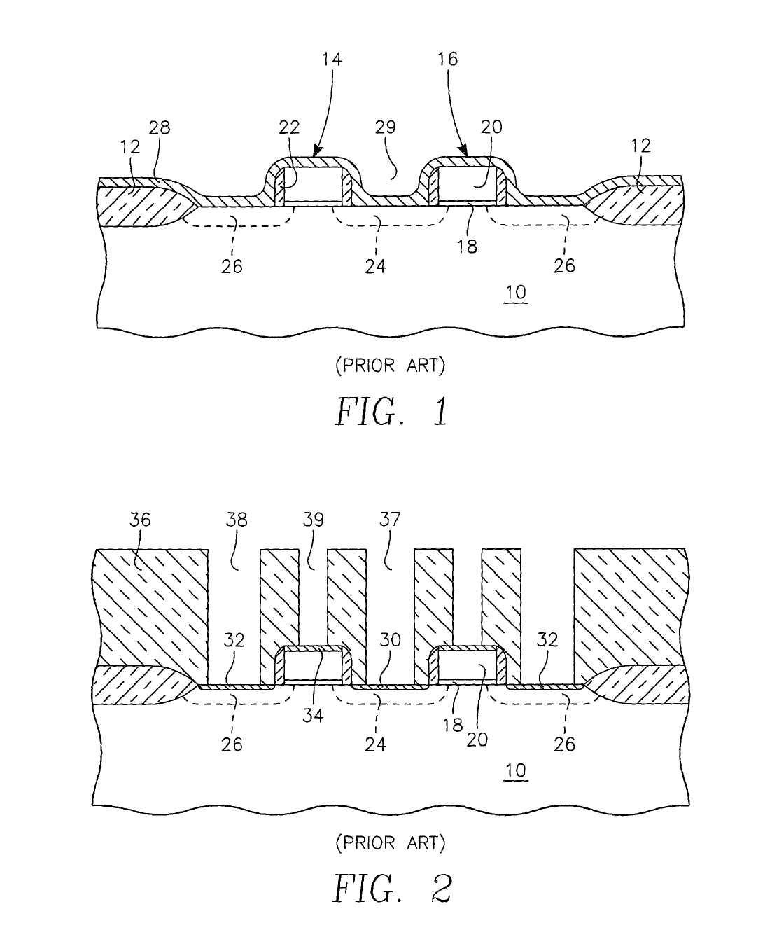

A pair of experiments were performed for sputtering cobalt into a 0.33 μm-wide, 1.2 μm-deep contact hole. This geometry does not correspond to that of FIG. 1, but the experimental results can be translated to the illustrated structure as well as to other siliciding processes. One experiment was performed according to the invention with a ring collimator; the other comparative experiment was performed without the collimator. In both cases, 4 kW of DC power was applied to the cobalt target, the pedestal was left electrically floating, and the chamber pressure was maintained at 1 milliTorr while the wafer was maintained at room temperature. The collimated sputtering was slower, requiring 60 seconds to deposit a 90 nm blanket thickness while the non-collimate sputtering required 34 seconds for a 77 nm blanket thickness. However, the thickness non-uniformity for collimated sputtering was about 5.5% while that for non-collimated sputtering was about 9.0%. These non-uniformity values were determined by differencing the maximum and minimum thicknesses and dividing by twice the average thickness. The sheet resistance for the collimated film was about 1.31 Ω/□ while that for non-collimated film was 1.51 Ω/□ with a resistance non-uniformity of 3.9% for the collimated film and 7.9% for the non-collimated film. An important parameter for depositing cobalt for siliciding at the bottom of a high aspect-ratio hole is the bottom coverage, which is the ratio of the thickness deposited at the bottom of the hole to blanket thickness on the planar top of the dielectric. For collimated sputtering, the bottom coverage was 23%; for non-collimated sputtering, it was 11%. As a result, even the reduced blanket deposition rate resulting from collimation produces equivalent bottom deposition.

Another pair of experiments were performed in fabricating short-gate MOS transistors with 5 nm-thick silicide layers with either collimated or uncollimated sputtering of the cobalt. The collimated sputtering was observed to produce less damage in the silicon as measured by the break-down voltage. Further, when the pedestal is left floating, it is observed to develop a negative self-bias of about −20 to −30VDC in the absence of a collimator, but virtually zero self-bias develops when a grounded collimator is interposed between the target and the wafer. It is believed that collimator grounds the electrons. The lack of negative self-bias on the wafer reduces the energy of any ion incident upon it, thus reducing silicon damage.

These parameters are considered quite adequate for deposition of the amount of cobalt necessary for siliciding.

Although the results are immediately applicable to sputtering cobalt, sputtering of other magnetic materials, such as iron and nickel, will benefit from the same apparatus. The method is also being applied to sputtering platinum and molybdenum.

The invention is not limited to the illustrated sputtering reactor, and many modifications may be made. For example, other magnetrons may be used, such as the nested unbalanced magnetrons of SIP sputtering, which are typically in a triangular form with the apex near the rotation axis and the base near the target periphery.

The invention allows the effective sputtering of cobalt and other magnetic materials into high aspect-ratio holes with only uncomplicated and inexpensive modifications from conventional aluminum sputtering reactors. The use of the bottom shield for supporting a collimator as well simplifies the design of sputter reactors used for non-magnetic materials.

1. A magnetron sputter reactor for sputtering a magnetic material, comprising:
a target disposed on a side of a plasma reaction chamber and comprising a magnetic material and configured to be connected to a DC power supply;
a pedestal disposed in said chamber for supporting a wafer having a diameter at a position separated from said target by a throw distance of at least 50% of said diameter;
a magnetron positioned on a side of said target opposite said pedestal;
a grounded shield disposed in said chamber to protect sidewalls and a bottom wall of said chamber and sides of said pedestal from sputter deposition; and
a grounded collimator positioned between said pedestal and said target.

2. The reactor of claim 1, wherein said magnetic material comprises metallic cobalt.

3. The reactor of claim 2, wherein said collimator is supported on and electrically connected to said bottom shield.

4. The reactor of claim 2, wherein said pedestal is electrically floating.

5. The reactor of claim 2, further comprising an RF power source electrically biasing said pedestal.

6. The reactor of claim 2, wherein a side of said collimator facing said target is separated from said wafer by no more than 40% of said throw distance.

7. The reactor of claim 2, wherein said chamber is maintained at a pressure of no more than 1 milliTorr.

8. The reactor of claim 1, wherein said collimator is supported on and electrically connected to said bottom shield.

9. The reactor of claim 1, wherein said chamber is maintained at a pressure of no more than 1 milliTorr.

10. A magnetron sputter reactor for sputtering a magnetic material, comprising:
a target disposed on a side of a plasma reaction chamber and comprising a magnetic material and configured to be connected to a DC power supply;
an electrically floating pedestal disposed in said chamber for supporting a wafer;
a magnetron positioned on a side of said target opposite said pedestal; and
a grounded collimator positioned between said pedestal and said target

11. The reactor of claim 10, wherein said magnetic material comprises cobalt.

12. The reactor of claim 10, wherein said wafer has a diameter and is supported on said pedestal at a position separated from said target by a throw distance of at least 50% of said diameter.

13. The reactor of claim 10, further comprising a grounded shield disposed in said chamber to protect sidewalls and a bottom wall of said chamber and sides of said pedestal from sputter deposition and wherein said collimator is supported on and electrically connected to said grounded shield.

14. A plasma sputter reactor, comprising:
a target disposed on a side of a plasma reaction chamber and comprising a material to be sputtered and configured to be connected to a DC power supply;
a pedestal disposed in said chamber for supporting a wafer to be sputter coated;
a magnetron positioned on a side of said target opposite said pedestal;
a grounded shield disposed in said chamber to protect sidewalls and a bottom wall of said chamber and sides of said pedestal from sputter deposition; and
a grounded collimator positioned between said pedestal and said target and supported and electrically fixed to said grounded shield.

15. The reactor of claim 14, wherein said shield comprises a tubular upper portion generally of a first diameter and a tubular lower portion generally of a second diameter less than said first diameter and connected by a radially extending ledge on which said collimator is supported.

16. The reactor of claim 14, wherein said material is a magnetic material.

17. The reactor of claim 16, wherein said magnetic material is metallic cobalt.

18. A plasma process for sputtering a magnetic material onto a substrate in a magnetron sputtering chamber having a target of a magnetic material disposed within, a pedestal to support said substrate in spaced relationship to the target, and a shield arrangement protecting the chamber sidewalls, chamber bottom, and pedestal sides, comprising the steps of:
applying a DC voltage to the target;
supporting a substrate on the pedestal at a distance with respected to the target of at least 50% of the diameter of the wafer;
providing a collimator between the pedestal and the target;
rotating the magnetron over a side of the target opposite the pedestal; and
grounding the shield arrangement and collimator.

19. The process of claim 18, further comprising maintaining a pressure in said chamber of no more than 2 milliTorr.

20. The process of claim 18, wherein said magnetic material comprises cobalt.
